(19) United States
(12) Patent Application Publication
(10) Pub. No.: US 2015/0060929 A1
(43) Pub. Date: Mar. 5, 2015

(54) CERAMIC CIRCUIT BOARD AND LED PACKAGE MODULE USING THE SAME

(71) Applicant: IBIS INNOTECH INC., Taichung City (TW)

(72) Inventor: Wei-Jen LAI, Jhubei City (TW)

(73) Assignee: IBIS INNOTECH INC., Taichung City (TW)

(21) Appl. No.: 14/171,432

(22) Filed: Feb. 3, 2014

(30) Foreign Application Priority Data
Sep. 5, 2013 (TW) 102216723

(51) Int. Cl. H05K 1/03; H01L 33/48

(52) U.S. Cl. CPC H05K 1/0306; H01L 33/486; H05K 2201/0175
USPC 257/99; 174/255

(57) ABSTRACT

A ceramic circuit board includes a substrate made of Al₂O₃ or AlN and having an exterior surface and a groove recessed from the exterior surface. The groove has a bottom surface provided with a roughness Ra of 1-20 μm, a plurality of crests and a plurality of troughs. The crests are located in an imaginary plane separated from the exterior surface at a distance of 1-100 μm. An electro-conductive wire is embedded in the groove and has a top surface flush with the exterior surface. An LED package module includes a ceramic circuit board having two embedded electro-conductive wires, two bonding pads respectively mounted on the top surfaces of the wires, and an LED chip having two contacts electrically connected with the bonding pads respectively. The electro-conductive wire is connected with the substrate firmly and made relatively thicker capable of carrying a relatively larger electric current.

### BACKGROUND OF THE INVENTION

1. Field of the Invention

The present invention relates generally to circuit boards and more particularly, to a ceramic circuit board and an LED package module using the ceramic circuit board.

2. Description of the Related Art

A conventional ceramic circuit board primarily comprises a substrate made of ceramic material, and a plurality of electro-conductive wires mounted on an exterior surface of the substrate. Because the substrate made of ceramic material is higher in thermal conductivity, heat resistance and electric insulativity than traditional substrates, the ceramic circuit board is applicable in electrical products having high heat-emitting rate, such as high-brightness LED.

In a manufacturing process of the ceramic circuit board, a seed layer is at first provided on the exterior surface of the substrate by sputtering with an electro-conductive material such as copper. After that, the electro-conductive wires are developed on the seed layer by photolithography and electroplating with a metal material such as copper. At this time, the electro-conductive wires can optionally be plated with bonding pads at predetermined positions according to applications of the ceramic circuit board, such as LED package modules. After that, spare parts of the seed layer exposed on the exterior surface of the substrate without being covered by the electro-conductive wires are removed by etching.

In the aforesaid ceramic circuit board, the electro-conductive wires are protruded from the exterior surface of the substrate, resulting in structural infirmness of the ceramic circuit board. At present, electronic elements are tending to be miniaturized in size, so the electro-conductive wires of the ceramic circuit board are correspondingly developed thinner and thinner. However, the thinner the electro-conductive wire is, the smaller connecting area and the less structural firmness are between the electro-conductive wire and the substrate. Besides, when the aforesaid spare parts of the seed layer are removed, the other parts of the seed layer located between the electro-conductive wires and the substrate are liable to be removed fractionally, resulting in further decrease of the structural firmness between the electro-conductive wires and the substrate. In addition, the width and the thickness of the electro-conductive wire are respectively limited by usage requirement and sputtering, so the electro-conductive wire can only carry a small electric current.

### SUMMARY OF THE INVENTION

The present invention has been accomplished in view of the above-noted circumstances. It is an objective of the present invention to provide a ceramic circuit board wherein an electro-conductive wire is mounted to a substrate firmly and capable of carrying a relatively larger electric current.

To attain the above objective, the present invention provides a ceramic circuit board which comprises a substrate and an electro-conductive wire. The substrate is made of aluminum oxide (Al₂O₃) or aluminum nitride (AlN) and has an exterior surface and a groove recessed from the exterior surface. The groove has a bottom surface provided with an arithmetic mean roughness (hereinafter referred to as “roughness Ra”) of 1-20 μm, a plurality of crests and a plurality of troughs. The crests are substantially located in an imaginary plane substantially parallel to and separated from the exterior surface at a distance of 1-100 μm. The electro-conductive wire is embedded in the groove of the substrate and has a top surface substantially flush with the exterior surface of the substrate.

As a result, the electro-conductive wire is completely located in the groove of the substrate; besides, the groove is quite deep and the bottom surface of the groove is quite lumpy. Therefore, the connection between the electro-conductive wire and the substrate is relatively firmer. In addition, the electro-conductive wire can be made quite thick for carrying a relatively larger electric current.

It is another objective of the present invention to provide an LED package module which is firm in structure and capable of carrying relatively larger electric currents.

To attain the above objective, the present invention provides an LED package module which comprises a substrate, two electro-conductive wires, two bonding pads and an LED chip. The substrate is made of aluminum oxide (Al₂O₃) or aluminum nitride (AlN) and has an exterior surface and two grooves recessed from the exterior surface. Each of the grooves has a bottom surface provided with a roughness Ra of 1-20 μm, a plurality of crests and a plurality of troughs. The crests are substantially located in an imaginary plane substantially parallel to and separated from the exterior surface at a distance of 1-100 μm. Said two electro-conductive wires are embedded in said two grooves of the substrate respectively. Each of the electro-conductive wires has a top surface substantially flush with the exterior surface of the substrate. Said two bonding pads are mounted on the top surfaces of said two electro-conductive wires, respectively. The LED chip has two contacts electrically connected with said two bonding pads, respectively.

As a result, the electro-conductive wires are connected with the substrate relatively more firmly and can be made thicker than electro-conductive wires of a conventional ceramic circuit board so that the electro-conductive wires in the present invention are capable of carrying relatively larger electric currents. Therefore, the LED package module is firm in structure and capable of carrying relatively larger electric currents.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a top schematic view of a ceramic circuit board according to a preferred embodiment of the present invention;

FIG. 2 is a sectional schematic view of the ceramic circuit board according to the preferred embodiment of the present invention;

FIG. 3 is a top schematic view of an LED package module using the ceramic circuit board;

FIG. 4 is a sectional schematic view of the LED package module;

FIG. 5 is a sectional schematic view of a first comparative ceramic circuit board;

FIG. 6 is a photograph of a real product according to the first comparative ceramic circuit board;

FIG. 7 is a sectional schematic view of a second comparative ceramic circuit board;

FIG. 8 is a photograph of a real product according to the second comparative ceramic circuit board;

FIG. 9 is a sectional schematic view of a third comparative ceramic circuit board;

FIG. 10 is a photograph of a real product according to the third comparative ceramic circuit board; and

FIGS. 11-16 are photographs of real products according to first to sixth examples of ceramic circuit board of the present invention.

### DETAILED DESCRIPTION OF THE INVENTION

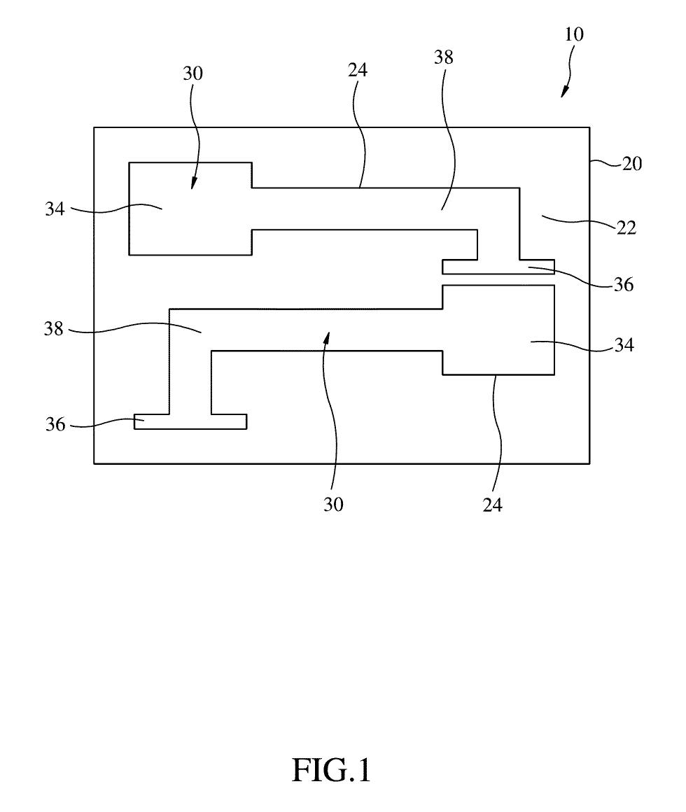

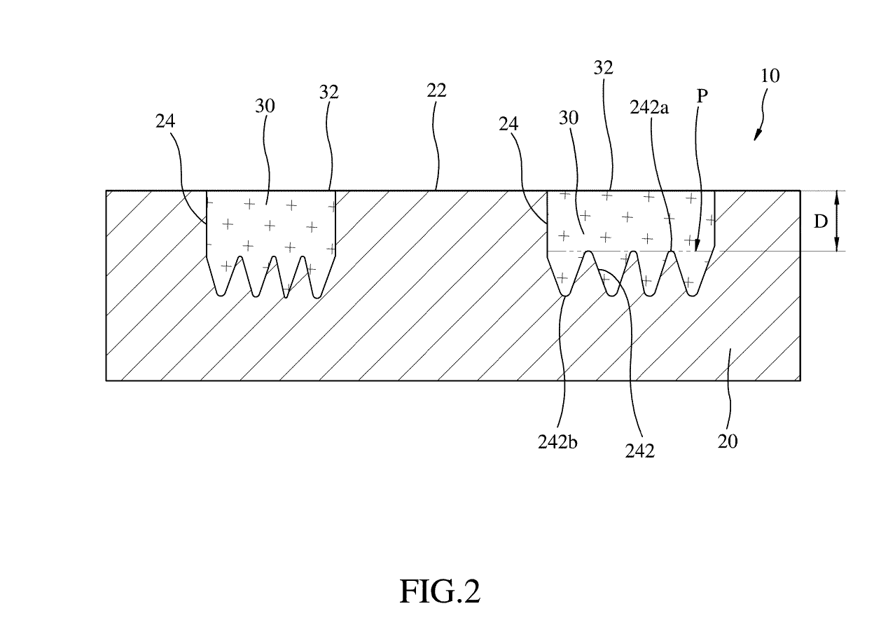

Referring to FIGS. 1-2, a ceramic circuit board 10 according to a preferred embodiment of the present invention comprises a substrate 20 and two electro-conductive wires 30 fixedly embedded in the substrate 20.

The substrate 20 is made of a ceramic material, including aluminum oxide (Al₂O₃) and aluminum nitride (AlN), and has an exterior surface 22 and two grooves 24 recessed from the exterior surface 22. Each of the grooves 24 has a bottom surface 242 provided with a roughness Ra of 1-20 μm. This means in microscopic view, the bottom surface 242 of each groove 24 is lumpy and has a plurality of crests 242a and a plurality of troughs 242b. The crests of the bottom surface 242 of each groove 24 are approximately located in an imaginary plane P which is approximately parallel to the exterior surface 22 and separated from the exterior surface 22 at a distance of 1-100 μm. In other words, each groove 24 can be defined with a depth D which is the distance between the imaginary plane P and the exterior surface 22 and ranged from 1 μm to 100 μm.

Said two electro-conductive wires 30 are made of metals having high electric conductivity, such as copper (Cu), silver (Ag) or gold (Au), and embedded in said two grooves 24, respectively. Each of the electro-conductive wires 30 has a top surface 32 approximately flush with the exterior surface 22 of the substrate 20. In other words, the electro-conductive wires 30 are complementary in shape to the grooves 24 of the substrate 20. In this embodiment, each of the electro-conductive wires 30 has a rectangular first bonding portion 34, a rectangular second bonding portion 36 narrower than the first bonding portion 34, and a connecting portion 38 connecting the first and second bonding portions 34, 36.

It will be appreciated that the electro-conductive wires 30 shown in FIG. 2 are sketched to only show a pair of adjacent said first and second bonding portions 34, 36, respectively. The rest of the electro-conductive wires 30 are not shown in FIG. 2.

In fact, the characteristics of the present invention are the depth D of the grooves 24, the roughness of the bottom surfaces 242 of the grooves 24, and a feature that the electro-conductive wires 30 are completely embedded in the grooves 24 and flush with the exterior surface 22 of the substrate 20. The amounts of the grooves 24 and the electro-conductive wires 30 and their shapes shown on the exterior surface 22 are not limited but modifiable according to different applications.

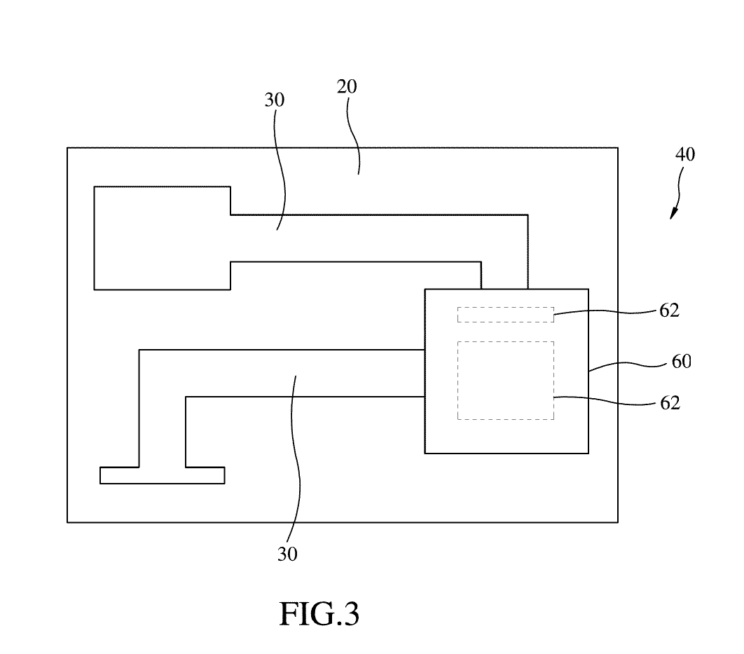

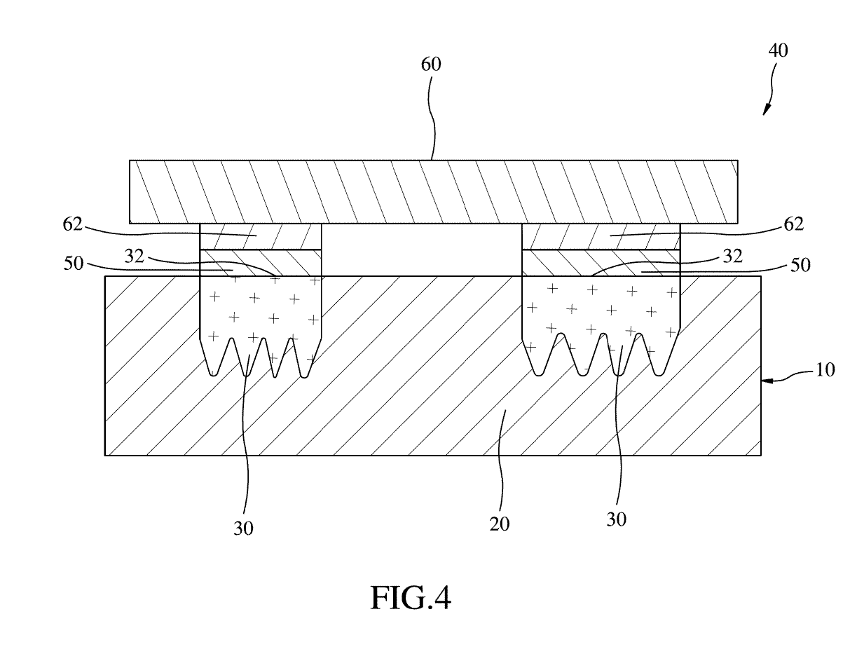

FIGS. 3-4 illustrate an LED package module 40 using the aforesaid ceramic circuit board 10. In addition to the aforesaid substrate 20 and electro-conductive wires 30, the LED package module 40 further comprises two bonding pads 50 and an LED chip 60.

Said two bonding pads 50 are plated and mounted on the top surfaces 32 of said two electro-conductive wires 30, respectively. In this embodiment, said two bonding pads 50 are located on a pair of adjacent said first and second bonding portions 34, 36 (referring to FIG. 1), respectively. The electro-conductive wires 30 shown in FIG. 4 are respectively sketched to show a said first bonding portion 34 and a said second bonding portion 36 connected with said two bonding pads 50 only. The rest of the electro-conductive wires 30 are not shown in FIG. 4. Each of the bonding pads 50 can be made of silver (Ag), tin (Sn), a layer of nickel (Ni) coated with a layer of gold (Au), or a layer of nickel (Ni) coated with a layer of silver (Ag).

The LED chip 60 is fixed to said two bonding pads 50 in a way of flip chip bonding. That is, the LED chip 60 has two contacts 62 protruding downward and fastened to said two bonding pads 50 respectively by welding. In this way, said two contacts 62 are electrically connected with said two bonding pads 50 respectively so as to be electrically connected with said two electro-conductive wires 30 respectively.

In the ceramic circuit board 10, the electro-conductive wires 30 are completely located in the grooves 24 of the substrate 20 and made quite thick because the grooves 24 are quite deep (depth D is 1-100 μm); besides, the bottom surfaces 242 of the grooves 24 are quite lumpy (roughness Ra is 1-20 μm). Therefore, the connection between each electro-conductive wire 30 and the substrate 20 is very firm, and the electro-conductive wire 30 is capable of carrying a relatively larger electric current because of relatively larger thickness thereof. Due to the aforesaid characteristics of the ceramic circuit board 10, the LED package module 40 is firm in structure and capable of carrying relatively larger electric currents.

In fact, the roughness Ra of the bottom surface 242 of each groove 24 is preferably in a range of 1-10 μm and more preferably in a range of 5-10 μm for achieving firmer connection between the electro-conductive wire 30 and the substrate 20. In addition, the depth D of each groove 24, i.e. the distance between the imaginary plane P and the exterior surface 22, is preferably in a range of 1-70 μm and more preferably in a range of 1-30 μm to minimize the quantity of metal used for electro-conductive wires 30 and time for electroplating so as to lower manufacturing cost.

In the following paragraphs, results of manufacturing ceramic circuit boards practiced by the inventor of the present invention will be disclosed and verify that the aforesaid numerical ranges of features in the present invention can cause a good result that the electro-conductive wires are fixed to the substrate firmly.

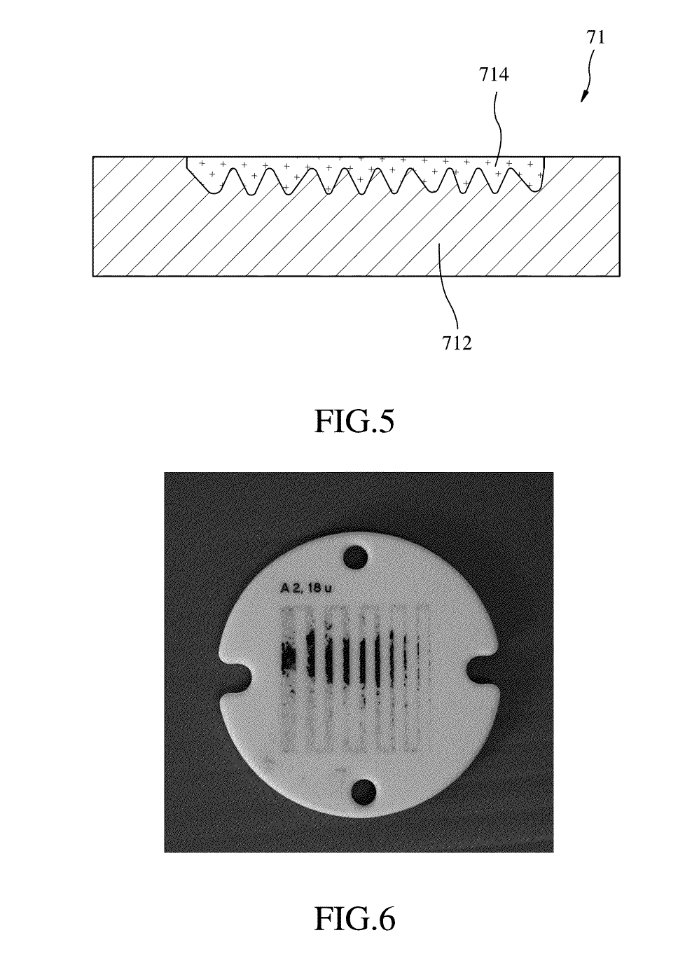

FIGS. 5, 7 and 9 are sectional schematic views of first, second and third comparative ceramic circuit boards 71, 72, 73 respectively, which are three comparative examples disaccording to numerical values provided by the present invention. Each of the ceramic circuit boards 71, 72, 73 comprises a substrate 712, 722, 732 and an electro-conductive wire 714, 724, 734 embedded in a groove of the substrate 712, 722, 732. FIGS. 6, 8 and 10 are photographs of real products according to the ceramic circuit boards 71, 72, 73, wherein the groove of the substrate has ten segments parallel to each other and each segment is wider than every segment at its right side.

In the first comparative ceramic circuit board 71 shown in FIG. 5, a depth of the groove of the substrate 712, which has the same definition as the aforesaid depth D, and a roughness Ra of a bottom surface in the groove are both less than 1 μm, i.e. below the aforesaid numerical range of the depth D and roughness Ra provided by the present invention. As shown in FIG. 6, in the real ceramic circuit board manufactured according to the first comparative ceramic circuit board 71, only one third of the groove is plated with metal, meaning that the groove can't be plated with the complete electro-conductive wire.

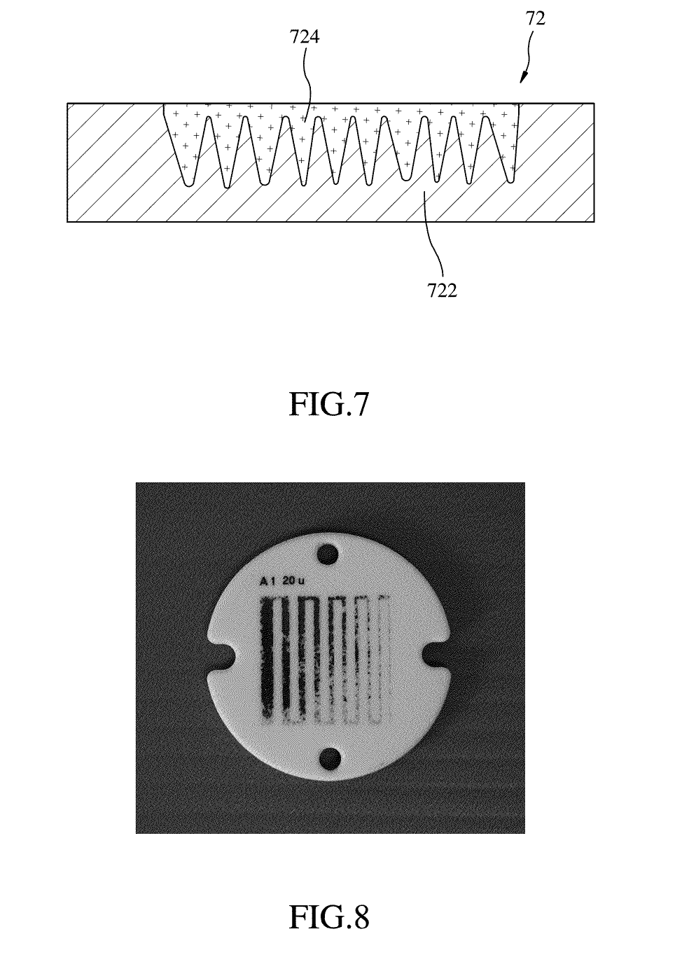

In the second comparative ceramic circuit board 72 shown in FIG. 7, a depth of the groove of the substrate 722, which has the same definition as the aforesaid depth D, is less than 1 μm; a roughness Ra of a bottom surface in the groove is more than 1 μm. That is, the roughness of the bottom surface fulfills the aforesaid numerical values provided by the present invention but the depth doesn't. As shown in FIG. 8, in the real ceramic circuit board manufactured according to the second comparative ceramic circuit board 72, almost half of the groove is not plated with metal, meaning that the groove can't be plated with the complete electro-conductive wire.

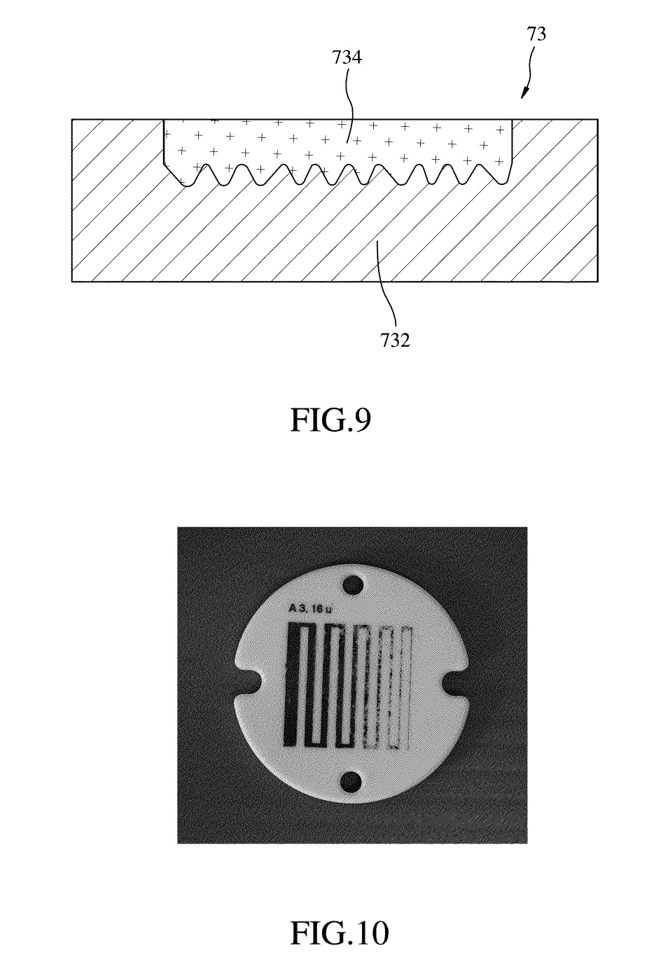

In the third comparative ceramic circuit board 73 shown in FIG. 9, a depth of the groove of the substrate 732, which has the same definition as the aforesaid depth D, is more than 1 μm; a roughness Ra of a bottom surface in the groove is less than 1 μm. That is, the depth fulfills the aforesaid numerical values provided by the present invention but the roughness of the bottom surface doesn't. As shown in FIG. 10, in the real ceramic circuit board manufactured according to the third comparative ceramic circuit board 73, almost one third of the groove is not plated with metal, meaning that the groove can't be plated with the complete electro-conductive wire.

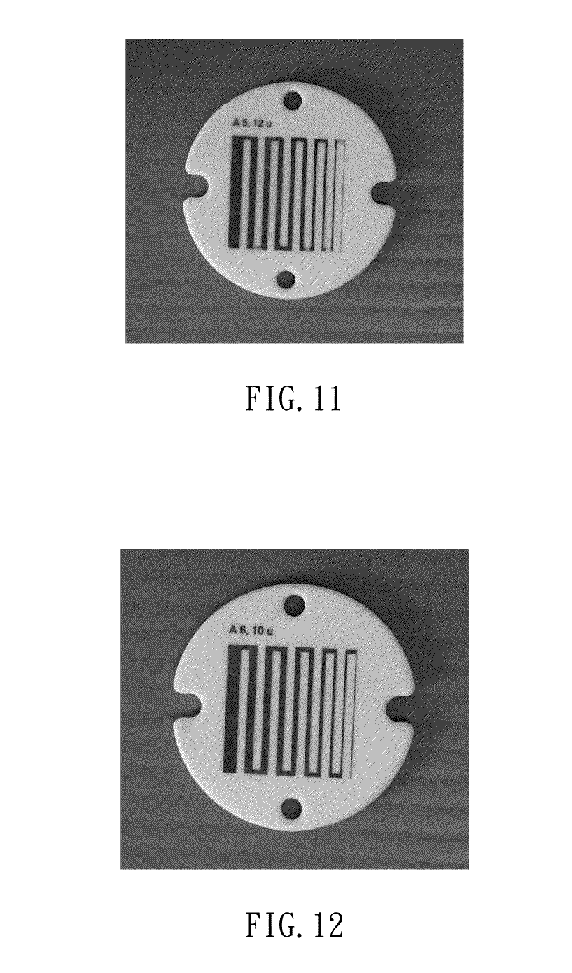

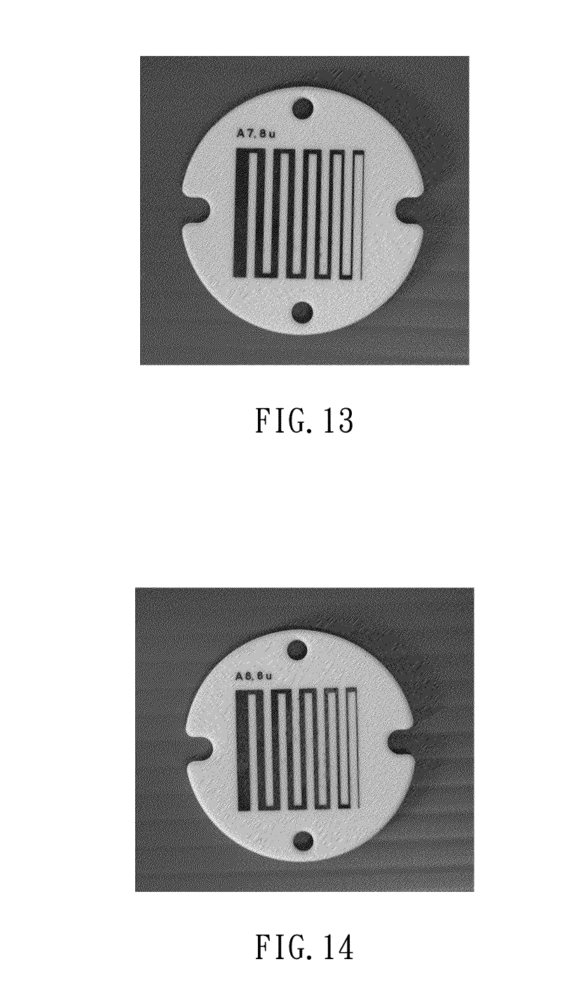

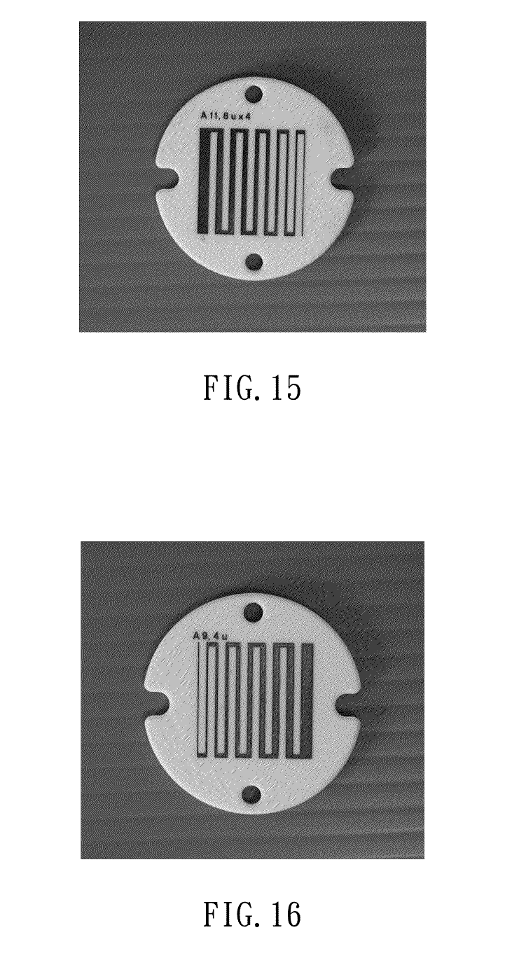

Referring to a table 1 below, wherein first to sixth examples of ceramic circuit board of the present invention are listed, the depths D of the grooves in the examples are different from each other but all in the range of 1-100 μm and the roughness Ra of the bottom surface in the groove of each example is in the range of 1-20 μm. FIGS. 11-16 are photographs of real products made according to the first to sixth examples listed in the table 1 in order and show that the groove in each of the examples can be plated with the complete electro-conductive wire.

TABLE 1

parameter

| example | depth (μm) | roughness Ra (μm) |
|---|---|---|
| 1 | 1-10 | 1-3 |
| 2 | 10-20 | 3-5 |
| 3 | 20-30 | 3-5 |
| 4 | 30-40 | 5-10 |
| 5 | 40-50 | 5-10 |
| 6 | 60-70 | 5-10 |

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A ceramic circuit board comprising:
a substrate made of aluminum oxide (Al₂O₃) or aluminum nitride (AlN) and having an exterior surface and a groove recessed from the exterior surface, the groove having a bottom surface provided with a roughness Ra of 1-20 μm, a plurality of crests and a plurality of troughs, the crests being substantially located in an imaginary plane substantially parallel to and separated from the exterior surface at a distance of 1-100 μm; and
an electro-conductive wire embedded in the groove of the substrate and having a top surface substantially flush with the exterior surface of the substrate.

2. The ceramic circuit board as claimed in claim 1, wherein the roughness Ra of the bottom surface in the groove of the substrate is 1-10 μm.

3. The ceramic circuit board as claimed in claim 2, wherein the roughness Ra of the bottom surface in the groove of the substrate is 5-10 μm.

4. The ceramic circuit board as claimed in claim 1, wherein the distance between the imaginary plane and the exterior surface is 1-70 μm.

5. The ceramic circuit board as claimed in claim 4, wherein the distance between the imaginary plane and the exterior surface is 1-30 μm.

6. An LED package module comprising:
a substrate made of aluminum oxide (Al₂O₃) or aluminum nitride (AlN) and having an exterior surface and two grooves recessed from the exterior surface, each of the grooves having a bottom surface provided with a roughness Ra of 1-20 μm, a plurality of crests and a plurality of troughs, the crests being substantially located in an imaginary plane substantially parallel to and separated from the exterior surface at a distance of 1-100 μm;
two electro-conductive wires embedded in said two grooves of the substrate respectively, each of the electro-conductive wires having a top surface substantially flush with the exterior surface of the substrate;
two bonding pads mounted on the top surfaces of said two electro-conductive wires respectively; and
an LED chip having two contacts electrically connected with said two bonding pads respectively.

7. The LED package module as claimed in claim 6, wherein the roughness Ra of the bottom surface in the groove of the substrate is 1-10 μm.

8. The LED package module as claimed in claim 7, wherein the roughness Ra of the bottom surface in the groove of the substrate is 5-10 μm.

9. The LED package module as claimed in claim 6, wherein the distance between the imaginary plane and the exterior surface is 1-70 μm.

10. The LED package module as claimed in claim 9, wherein the distance between the imaginary plane and the exterior surface is 1-30 μm.
